(19) United States
(12) Patent Application Publication
(10) Pub. No.: US 2026/0198111 A1
(43) Pub. Date: Jul. 9, 2026

(54) IMAGE SENSING DEVICE AND IMAGING SYSTEM INCLUDING THE SAME

(71) Applicant: SK hynix Inc., Icheon-si (KR)

(72) Inventors: Dong Ha KIM, Icheon-si (KR); Han Jun KIM, Icheon-si (KR)

(21) Appl. No.: 19/200,233

(22) Filed: May 6, 2025

(30) Foreign Application Priority Data
Jan. 6, 2025 (KR) 10-2025-0001524

(51) Int. Cl. H10F 39/00

(52) U.S. Cl. CPC H10F 39/8027; H10F 39/807

(57) ABSTRACT

Disclosed is an image sensing device, which includes a substrate; a first pixel region, a second pixel region, and a third pixel region that are supported by the substrate; a third pixel region positioned in a second direction of the first pixel region and supported by the substrate, wherein each of the first to third pixel regions includes one or more photoelectric conversion elements, a first non-pixel region and a second non-pixel region that do not include a photoelectric conversion element for detecting incident light; at least one first insulation material and at least one second insulation material that are disposed in the first non-pixel region and the second non-pixel region, respectively; wherein the at least one first insulation material disposed in the first non-pixel region is different from the at least one second insulation material disposed in the second non-pixel region.

### PRIORITY AND CROSS REFERENCE TO RELATED APPLICATION

This patent document claims priority to Korea Patent Application No. 10-2025-0001524, filed Jan. 6, 2025, the entire contents of which is incorporated herein for all purposes by this reference.

### TECHNICAL FIELD

Implementations of the disclosed technology relate to an image sensing device and an imaging system including the same.

### BACKGROUND

Recently, with the development of information and communication technologies and the digitalization of image information, electrical devices, such as a digital camera, a camcorder, a mobile phone, a personal communication system (PCS), a game machine, security camera and a medical micro camera, are now equipped with image sensors having the improved performance. In general, the image sensor may include a pixel region which includes a photodiode and a peripheral circuit region. A unit pixel may include a photodiode and a transfer transistor. The transfer transistor may be disposed between the photodiode and a floating diffusion region and may transfer charges generated by the photodiode to the floating diffusion region.

### SUMMARY

Some implementations of the disclosed technology provide an image sensing device capable of optimizing a light reflectance by applying insulation layers having each different characteristic in a boundary between pixel regions, each of which is configured to receive a different color.

In one aspect, an image sensing device is provided to include: a substrate; a first pixel region supported by the substrate; a second pixel region positioned in a first direction of the first pixel region and supported by the substrate; a third pixel region positioned in a second direction of the first pixel region and supported by the substrate, wherein each of the first pixel region, the second pixel region, and the third pixel region includes one or more photoelectric conversion elements configured to produce electrical signals in response to incident light, a first non-pixel region that does not include a photoelectric conversion element for detecting incident light and is located between the first pixel region and the second pixel region to reflect light from the first pixel region back to the first pixel region and reflect light from the second pixel region back to the second pixel region; a second non-pixel region that does not include a photoelectric conversion element for detecting incident light and is located between the first pixel region and the third pixel region to reflect light from the first pixel region back to the first pixel region and reflect light from the third pixel region back to the third pixel region; at least one first insulation material and at least one second insulation material that are disposed in the first non-pixel region and the second non-pixel region, respectively; and wherein the at least one first insulation material disposed in the first non-pixel region is different from the at least one second insulation material disposed in the second non-pixel region.

In another aspect, an image sensing device is provided to comprise: a substrate including a first pixel region that includes one or more photoelectric conversion elements detecting incident light, a second pixel region that is positioned in a first direction of the first pixel region and includes one or more photoelectric conversion elements detecting incident light, a third pixel region that is positioned in a second direction of the first pixel region and includes one or more photoelectric conversion elements detecting incident light, a first non-pixel region that is located between the first pixel region and the second pixel region and does not detect incident light, and a second non-pixel region that is located between the first pixel region and the third pixel region and does not detect incident light, the substrate further including a hole in at least one of the first non-pixel region or the second non-pixel region; a separating structure disposed in the first non-pixel region and the second non-pixel region; and at least one first insulation material disposed in the first non-pixel region and between the separating structure and a side surface of the substrate, at least one second insulation material disposed in the second non-pixel region and between the separating structure and a side surface of the substrate, wherein the at least one first insulation material disposed in the first non-pixel region and the at least one second insulation material disposed in the second non-pixel region are different from each other.

Some implementations of the disclosed technology allow to optimize the light reflectance by applying different insulation layers in boundaries between pixel regions, each pixel region configured to transmit light in a different color.

The effects of the present disclosure are not limited to the above-described effects and other effects which are not described herein may be clearly understood by those skilled in the art from the following description of the embodiments of the present disclosure.

### BRIEF DESCRIPTION OF THE DRAWINGS

FIG. 1 is a diagram illustrating an imaging system based on some implementations of the disclosed technology.

FIG. 2 is a diagram illustrating an image sensing device in FIG. 1.

FIG. 3 is a plan view illustrating a pixel array according to FIG. 2.

FIG. 4 is a cross-sectional view taken along A-A′ line in FIG. 3.

FIG. 5 is a cross-sectional view taken along B-B′ line in FIG. 3.

FIG. 6 is a graph showing a reflectance per wavelength of each different sample.

FIG. 7 is a schematic view illustrating light reflection of a pixel array based on some implementations of the disclosed technology.

FIG. 8 is a schematic view illustrating light reflection of a pixel array based on some implementations of the disclosed technology.

FIG. 9 is a cross-sectional view of a pixel array of an image sensing device based on some implementations of the disclosed technology.

FIG. 10 is a plan view illustrating a pixel array of an image sensing device based on some implementations of the disclosed technology.

FIG. 11 is a cross-sectional view taken along C-C′ line in FIG. 10.

FIG. 12 is a cross-sectional view taken along D-D′ line in FIG. 10.

FIG. 13 is a cross-sectional view taken along E-E′ line in FIG. 10.

FIG. 14 is a cross-sectional view illustrating a pixel array of an image sensing device based on some implementations of the disclosed technology.

FIG. 15 is a cross-sectional view illustrating a pixel array of an image sensing device based on some implementations of the disclosed technology.

FIG. 16 is a cross-sectional view illustrating a pixel array of an image sensing device based on some implementations of the disclosed technology.

### DETAILED DESCRIPTION

Example embodiments will now be described with reference to the accompanying drawings.

Like reference numerals refer to like elements throughout. Additionally, in the drawings, the thicknesses, proportions, and dimensions of components may be exaggerated for ease of description and clarity. “And/or” includes all of one or more combinations defined by related components.

In various embodiments of the present disclosure, the terms “include,” “comprise,” “including,” or “comprising,” may refer to a property, a fixed number, a step, a process, a component or combination thereof, but do not exclude other properties, fixed numbers, steps, processes, components or combination thereof.

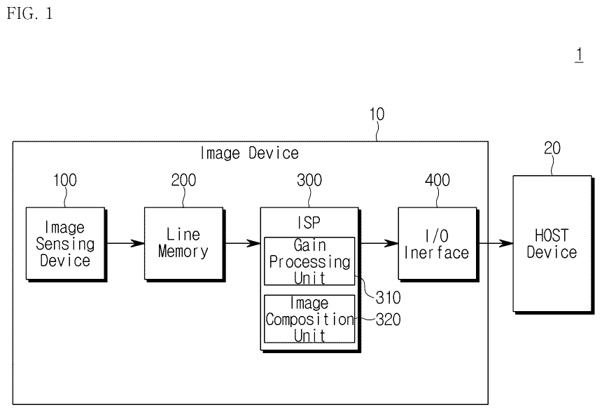

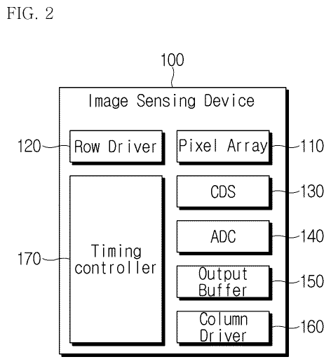

FIG. 1 is a diagram illustrating an imaging system according to an embodiment. FIG. 2 is a diagram illustrating an image sensing device in FIG. 1.

Referring to FIG. 1, the imaging system 1 may refer to not only a device, for example, a digital still camera for photographing still images or a digital video camera for photographing moving images, but also a device for detecting a motion. For example, the imaging device 10 may be implemented as a Digital Single Lens Reflex (DSLR) camera, a mirrorless camera, or a mobile phone (in particular, a smartphone), but is not limited thereto. The imaging device 10 may include a device having a lens and an image pickup element such that the device can capture a target object and can thus create an image of the target object.

The imaging system 1 may include an imaging device 10 and a host device 20.

The imaging device 10 may include an image sensing device 100, a line memory 200, an ISP (image signal processor) 300, and an I/O interface 400.

The image sensing device 100 may be or include a CIS (Complementary Metal Oxide Semiconductor Image Sensor) configured to convert an optical signal into an electric signal. The overall operations such as turning on/off, operation modes, operation timings, sensitivity, and others of the image sensing device 100 may be controlled by the ISP 300. The image sensing device 100 may convert the optical signal into the electrical signal to transmit image data to the line memory 200 based on the control of the ISP 300.

Referring to FIG. 2, the image sensing device 100 may include a pixel array 110, a row driver 120, a CDS 130 (Correlate Double Sampler), an ADC 140 (Analog-Digital Converter), an output buffer 150, a column driver 160, and a timing controller 170. Here, each component of the image sensing device 100 is discussed as the example only, and in some implementations, at least some components may be added or omitted.

The pixel array 110 may include a plurality of imaging pixels arranged in a plurality of rows and a plurality of columns. In an example, the plurality of imaging pixels may be arranged in a two-dimensional pixel array including rows and columns. In another example, the plurality of imaging pixels may be arranged in a three-dimensional pixel array. The plurality of imaging pixels may convert an optical signal into an electrical signal on a unit pixel basis or a pixel group basis, where the imaging pixels in a pixel group share at least a certain internal circuitry. The pixel array 110 may receive pixel control signals, including a row selection signal, a pixel reset signal and a transmission signal, from the row driver 120. Upon receiving the pixel control signals, corresponding pixels in the pixel array 110 may be activated to perform the operations corresponding to the row selection signal, the pixel reset signal, and the transmission signal. Each of the imaging pixels may generate photocharges corresponding to the intensity of incident light (or luminous intensity), may generate an electrical signal corresponding to the amount of photocharges, thereby sensing the incident light. For convenience of description, the imaging pixel may also be referred to as a pixel.

The row driver 120 may activate the pixel array 110 to perform certain operations on the imaging pixels in the corresponding row based on commands and control signals provided by the timing controller 170.

In an embodiment, the CDS 130 may sequentially sample and hold the reference signal and the image signal, which are provided to each of a plurality of column lines from the pixel array 110. That is, the CDS 130 may sample and hold levels of the reference signal and the image signal corresponding to each of the columns of the pixel array 110.

The CDS 130 may transfer the reference signal and the image signal of each of the columns as a correlate double sampling signal to the ADC 140 based on control signals from the timing controller 170.

The ADC 140 may convert the correlate double sampling signal output from the CDS 130 with respect to each column into digital signals, and output the image data. In an embodiment, the ADC 140 may convert the correlate double sampling signal output from the CDS 130 for each of columns into digital signals, and output the digital signals.

The ADC 140 may include a plurality of column counters corresponding to columns of the pixel array 110, respectively. Each of the columns of the pixel array 110 is connected to each column counter, and the image data may be generated by conversion of the correlate double sampling signal corresponding to each of the columns using the column counter.

The output buffer 150 may temporarily hold the column-based image data provided from the ADC 140 to output the image data. The output buffer 150 may temporarily store image data output from the ADC 140 based on the control signal of the timing controller 170.

The column driver 160 may select a column of the output buffer 150 based on a control signal from the timing controller 170, and may control the output buffer 150 to sequentially output the image data, which are temporarily stored in the selected column of the output buffer 150.

The timing controller 170 may control at least one among the row driver 120, the CDS 130, the ADC 254, the output buffer 150 and the column driver 160.

The timing controller 170 may provide at least one among the row driver 120, the CDS 130, the ADC 140, the output buffer 150 and the column driver 160 with a clock signal required for the operations of the respective components of the image sensing device 100, a control signal for timing control, and address signals for selecting a row or column. According to an embodiment, the timing controller 170 may include a logic control circuit, a phase lock loop (PLL) circuit, a timing control circuit, and a communication interface circuit, etc.

Referring back to FIG. 1, the line memory 200 may include a volatile memory (e.g., DRAM, SRAM, etc.) and/or a non-volatile memory (e.g., a flash memory).

The line memory 200 may receive image data from the image sensing device 100, may store the received image data, and may transmit the stored image data to the ISP 300 based on the control of the ISP 300.

The ISP 300 may perform image processing of the image data stored in the line memory 200. The ISP 300 may reduce noise of image data, and may perform image signal processing such as gamma correction, color filter array interpolation, color matrix, color correction, color enhancement, lens distortion correction, etc. for image-quality improvement.

In order to generate the HDR image, the ISP 300 may include a gain processing unit 310, and an image compositing unit 320.

The gain processing unit 310 may determine a gain to be calculated with (to be multiplied by) image data. The gain processing unit 310 may determine a gain according to a difference in the conversion gain between the an HCG (high conversion gain) mode and a LCG (low conversion gain) mode, and provide the determined gain to the image compositing unit 320.

Each of the pixels of the pixel array 110 may operate in any one mode among the HCG mode or the LCG mode, and a mode of each pixel may be determined according to a strength (or illuminance) of light incident into each pixel.

The image compositing unit 320 may synthesize HDR image corresponding to a high dynamic range by using the image data of the pixel operating in the HCG mode and/or the image data of the pixel operating in the LCG mode.

The ISP 300 may transmit image data (e.g., HDR image) obtained through such image signal processing to the I/O interface 400.

According to another embodiment, the gain processing unit 310, and the image compositing unit 320 for the generation of HDR image may be included in the image sensing device 100, rather than the ISP 300.

The I/O interface 400 may perform communication with the host device 20, and may transmit image data obtained through the image signal processing to the host device 20.

The host device 20 may be or include a processor configured to process the image data obtained through the image signal processing (for example, an application processor) and received from the imaging device 10, a memory configured to store image data (for example, a non-volatile memory), or a display device configured to visually output image data (for example, a liquid crystal display (LCD)).

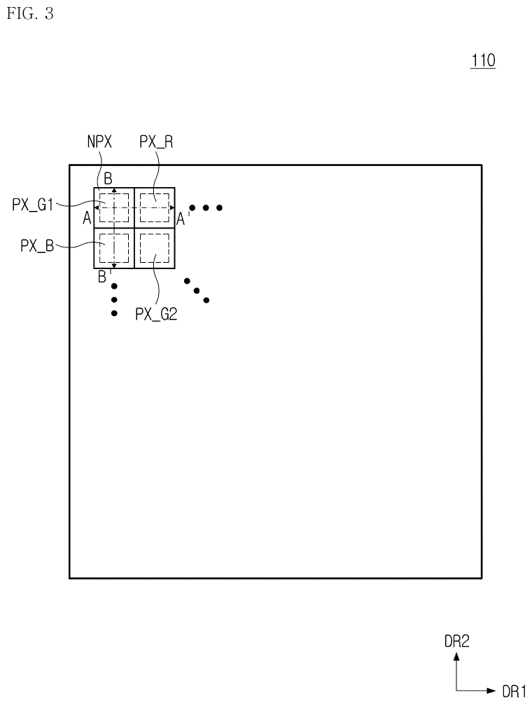

FIG. 3 is a plan view illustrating a pixel array according to FIG. 2. In various implementations, such a pixel array is supported by a substrate by suitable integrated circuit fabrication processes such as a complementary metal-oxide semiconductor (CMOS) process to construct the pixel array as a CMOS pixel array.

Referring to FIG. 3, the pixel array 110 according to an embodiment may include a plurality of pixels. The plurality of pixels may include a first pixel, a second pixel, a third pixel, and a fourth pixel. Each pixel may include pixel regions PX_R, PX_G1, PX_G2, and PX_B, and a non-pixel region NPX. The first pixel may be a green pixel which receives green light, the second pixel may be a red pixel which receives red light, the third pixel may be a blue pixel which receives blue light, and the fourth pixel may be a green pixel which receives green light. A color filter may be disposed in each of the pixels to select the color of the light that transmits through the color filter and different color filters on different adjacent pixels are used to capture the color information in an image carried by the incident light. During the daytime, each pixel may receive light in the corresponding wavelength range of a visible ray. In some implementations, the first pixel, the second pixel, the third pixel, and the fourth pixel may further receive light in the wavelength range of the infrared light. In the example, peak wavelengths of the first pixel and the fourth pixel may be a green wavelength and an infrared wavelength, peak wavelengths of the second pixel may be a red wavelength and the infrared wavelength, and peak wavelengths of the third pixel may be a blue wavelength and the infrared wavelength. Since there is little light within the wavelength range of the visible ray at night, each pixel may receive light within the infrared wavelength range per region. The plurality of pixels may be repeatedly disposed along a first direction DR1 and a second direction DR2, but are not limited thereto. Considering a peak wavelength range of the light to be received, a color filter may be disposed in each of the plurality of pixels. For example, a green color filter is disposed in the first pixel and the fourth pixel to transmit light in a green color while absorbing light in other colors such as blue and red colors, a red color filter is disposed in the second pixel to transmit light in a red color while absorbing light in other colors such as blue and green colors, and a blue color filter is disposed in the third pixel to transmit light in a blue color while absorbing light in other colors such as green and red colors.

In some embodiments, the plurality of pixels may further include a fifth pixel which receives white light, but the embodiments of the present disclosure are not limited thereto. For example, the fifth pixel may be configured to receive colored light other than the white light.

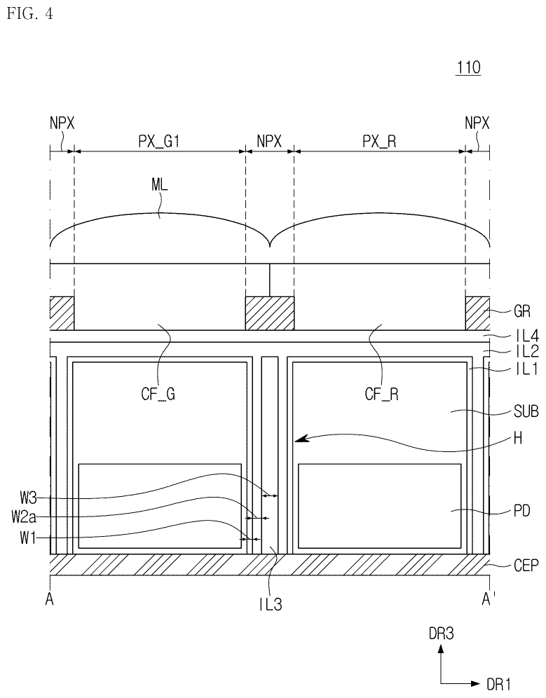

FIG. 4 is a cross-sectional view taken along A-A′ line in FIG. 3. In FIG. 4, a cross-sectional view of the pixel array of the first pixel and the second pixel is illustrated.

Referring to FIG. 4, the pixel array 110 according to an embodiment includes a circuit portion CEP, a substrate portion SUB disposed on the circuit portion CEP and including a hole H, insulation layers IL1, IL2, IL3 and IL4 on the substrate portion SUB, a grid portion GR on the insulation layers IL1, IL2, IL3 and IL4 in the non-pixel region NPX, color filters CF_G and CF_R on the grid portion GR, and a light receiving pattern ML on the color filters CF_G and CF_R. The non-pixel region NPX is a region without a photoelectric conversion element PD and thus does not detect incident light. In the example in FIG. 4, the non-pixel region NPX is located between two adjacent pixels and is structured to reflect light from the respective adjacent pixels back to the adjacent pixels to increase the reception at each photoelectric conversion element PD of the incident light entering that pixel, thus the overall optical detection efficiency, and, additionally, to reduce undesired optical crosstalk between adjacent pixels that would otherwise adversely reduce the image resolution and quality.

The circuit portion CEP may be disposed on a bottom surface of the substrate portion SUB, and may include at least one of transistors, a wiring layer, and/or an interlayer insulation layer. The transistors may include an overflow transistor, a transfer transistor, a reset transistor, a driving transistor, and a selection transistor, all of which are formed on the bottom surface of the substrate portion SUB.

The substrate portion SUB may include a single crystalline silicon wafer or an epitaxially grown single-crystalline silicon layer. The substrate portion SUB may have a high refractive index. For example, the refractive index of the substrate portion SUB may be about 2.5 or more, but is not limited thereto. For example, the refractive index of the substrate portion SUB may be about 4 to 6, but is not limited thereto.

The substrate portion SUB may include a photoelectric conversion element PD. The photoelectric conversion element PD may include a photodiode, or a photo detector, but the embodiments of the present disclosure are not limited thereto.

The photoelectric conversion element PD may be formed by injecting P-type ions and N-type ions. P-type ions may include boron (B) ions, and N-type ions may include phosphorous (P) ions and/or arsenic (As) ions. The photoelectric conversion element PD serves to convert the optical signals into the electric signals by receiving the incident light. The photoelectric conversion element PD may refer to only a portion which corresponds to the pixel regions PX_G1 and PX_R, but is not limited thereto.

A hole H may be formed in the substrate portion SUB. Each of the holes H may be formed by recessing the substrate portion SUB in a thickness direction. The hole H may be disposed in non-pixel region NPX, and may completely pass through the substrate portion SUB. However, in some embodiments, the hole may not be formed, and a groove which partially passes through the substrate portion SUB may be disposed. In another embodiment, a groove may be formed in the substrate portion SUB in the pixel region PX_G1 and PX_R. The groove disposed in the pixel region PX_G1 and PX_R may be one or more in number.

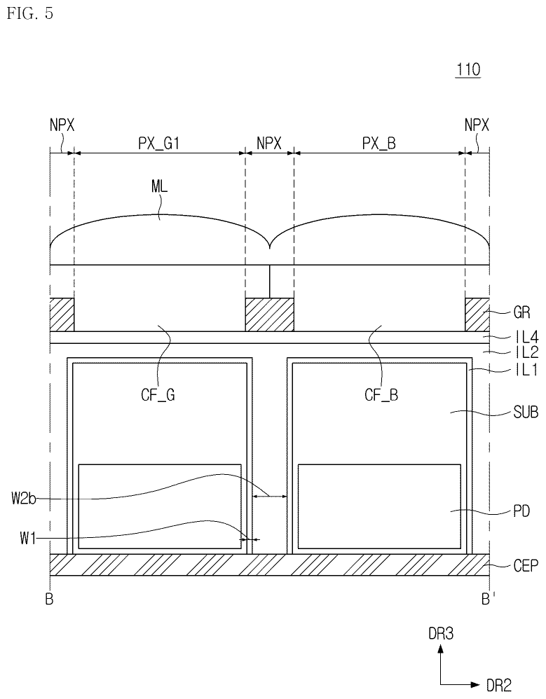

At least one insulation layer IL1, IL2, IL3 and IL4 may be disposed on the substrate portion SUB. Hereinafter, a non-pixel region NPX between the first pixel region PX_G1 and the second pixel region PX_R is defined as a first non-pixel region. In addition, a non-pixel region NPX between the first pixel region PX_G1 and the third pixel region PX_B is defined as a second non-pixel region, which will be described below referring to FIG. 5. In some implementations of the pixel array 110, at least one insulation layer disposed in the first non-pixel region and at least one insulation layer disposed in the second non-pixel region may be different from each other. Hereinafter, the insulation layers IL1, IL2, IL3 and IL4 will be described.

As illustrated in FIG. 4, a first insulation layer IL1 may be disposed on the substrate portion SUB. The first insulation layer IL1 may be disposed on side surfaces of the substrate portions SUB adjacent to each other and may be in direct contact with side surfaces of the substrate portions SUB adjacent to each other in the first non-pixel region. The first insulation layer IL1 may be in direct contact with an upper surface of the substrate portion SUB in each pixel region PX_G1 and PX_R. The first insulation layer IL1 may include aluminum oxide (AlOx), for example, but embodiments of the present disclosure are not limited thereto.

A second insulation layer IL2 may be disposed on the first insulation layer IL1. The second insulation layer IL2 may be disposed on a side surface of the substrate portion SUB in the first non-pixel region NPX, and may be in direct contact with the first insulation layer IL1 on the side surface of the substrate portion SUB. The second insulation layer IL2 may be disposed on a side surface of the first insulation layer IL1 and may be in direct contact with the side surface of the first insulation layer IL1. In some implementations, on a side surface of each of the substrate portions SUB adjacent to each other, the first insulation layers IL1 are disposed, and on a side surface of each of the first insulation layers IL1 disposed on the side surface of each of the adjacent substrate portions SUB, the second insulation layers IL2 are disposed. The second insulation layer IL2 may extend to an upper surface of the substrate portion SUB, and on the upper surface of the substrate portion SUB, the second insulation layer IL2 may be disposed on the first insulation layer IL1. The second insulation layer IL2 may be in direct contact with the first insulation layer IL1 on the upper surface of the substrate portion SUB. The second insulation layer IL2 may include, for example, hafnium oxide (HfOx) or tantalum oxide (TaOx), but embodiments of the present disclosure are not limited thereto.

A third insulation layer IL3 may be disposed between the second insulation layers IL2 on the side surfaces of the adjacent substrate portions SUB. The third insulation layer IL3 may include, for example, silicon oxide (SiOx), but embodiments of the present disclosure are not limited thereto.

On the upper surface of the substrate portion SUB, a fourth insulation layer IL4 may be disposed on the second insulation layer IL2. The fourth insulation layer IL4 may be in direct contact with the second insulation layer 2. The fourth insulation layer IL4 may include, for example, silicon oxide (SiOx), but embodiments of the present disclosure are not limited thereto.

The insulation layers IL1, IL2 and IL3 disposed in the first non-pixel region NPX between the pixel regions PX_G1 and PX_R may serve to reflect light incident into the first non-pixel region NPX to each of the pixel regions PX_G1 and PX_R. This optical reflection by the insulation layers IL1, IL2 and IL3 in the first non-pixel region NPX can provide benefits: increasing the reception at the photoelectric conversion element PD of each pixel of the incident light entering that pixel, thus improving the overall optical detection efficiency, and, second, reducing undesired optical crosstalk between two adjacent pixels that would otherwise adversely reduce the image resolution and quality.

On the side surface of the substrate portion SUB, the first insulation layer IL1 has a first width W1, the second insulation layer IL2 has a second width W2, and the third insulation layer IL3 has a third width W3. In an embodiment, the second width W2 may be greater than the first width W1, and smaller than the third width W3.

The first insulation layer IL1, the second insulation layer IL2 and the fourth insulation layer IL4, which are disposed on the upper surface of the substrate portion SUB, serve to not make light which passes through the color filters CF_G and CF_R be reflected, but be incident into the substrate portion SUB.

The grid portion GR may be disposed on the insulation layers IL1, IL2, and IL4 disposed on the upper surface of the substrate portion SUB. The grid portion GR may be disposed in the first non-pixel region NPX. The grid portion GR may absorb or reflect light incident into the grid portion GR because the grid portion GR is disposed in the first non-pixel region NPX. The grid portion GR may prevent color mixing between the adjacent pixel regions PX_G1 and PX_R. The grid portion GR may include a light absorbing material or a low refractive layer. For example, when the grid portion GR includes the light absorbing material, the grid portion GR may include a metal material. The metal material may include tungsten (W), but embodiments of the present disclosure are not limited thereto. For example, when the grid portion GR includes the low refractive layer, the grid portion GR may include a low refractive insulation material, or an air structure.

The color filters CF_G and CF_R may be disposed over the insulation layers IL1, IL2, and IL4 disposed on the upper surface of the substrate portion SUB and the grid portion GR. The second color filter CF_R may receive light in the red wavelength range and an infrared wavelength range and block light in the remaining wavelength range, and the first color filter CF_G may receive light in the green wavelength range and an infrared wavelength range and block light in the remaining wavelength range. For example, the second color filter CF_R may allow light in the red color and infrared light to transmit through the second color filter CF_R while absorbing light in other colors such as blue and red colors, and the first color filter CF_G may allow light in the green color and infrared light to transmit through the first color filter CF_G while absorbing light in other colors such as red and blue colors.

The light receiving pattern ML may be disposed on the color filters CF_G and CF_R. The light receiving pattern ML may serve to receive light incident from the outside into the pixel regions PX_G1 and PX_R. In some implementations, the light receiving pattern ML may have a shape of a convex lens that is convex upward, and may be formed of or include a material with a great difference in the refractive index compared to the refractive index of a material outside, for example, air. For example, the refractive index of the light receiving pattern ML can be, but is not limited to, about 1.5 to about 1.7. The light receiving pattern ML may be arranged continuously in the pixel regions PX_G1 and PX_R and the non-pixel region NPX, as shown in FIG. 4, and may be formed such that an end of the convex lens shape is positioned in the center of the pixel regions PX_G1 and PX_R, but is not limited to. For example, the light receiving pattern ML may be disconnected in the non-pixel region NPX, in which case the plurality of the light receiving patterns ML may be positioned in the pixel regions PX_G1 and PX_R, respectively. The light receiving pattern ML may include a microlens, but embodiments of the present disclosure are not limited thereto.

FIG. 5 is a cross-sectional view taken along B-B′ line in FIG. 3. A cross-sectional view of the pixel array of the first pixel and the third pixel is illustrated in FIG. 5. With respect to the components which have been described referring to FIG. 4, the redundant description thereof will be omitted.

Referring to FIG. 5, the pixel array 110 according to an embodiment may include the circuit portion CEP, the substrate portion SUB disposed on the circuit portion and including the hole H, the insulation layers IL1, IL2 and IL4 on the substrate portion SUB, the grid portion GR on the insulation layers IL1, IL2 and IL4 in the non-pixel region NPX, the color filters CF_G and CF_B on the grid portion GR, and the light receiving pattern ML on the color filters CF_G and CF_B.

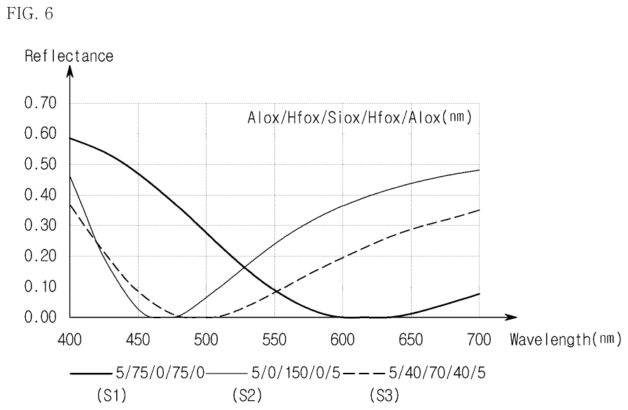

At least one insulation layers IL1, IL2 and IL4 may be disposed on the substrate portion SUB. The insulation layers IL1 and IL2 disposed in the second non-pixel region and the insulation layers IL1, IL2 and IL3 disposed in the first non-pixel region may be different from each other. The structures corresponding to the insulation layers IL1, IL2, and IL3 in each non-pixel region are different, and detailed explanations on the structures corresponding to IL1, IL2, and IL3 are provided in relation to FIG. 5. In some implementations, the insulation layers IL1, IL2, and IL4 may correspond to the stacking structures of various samples (S1, S2, S3) as described later in relation to FIG. 6.

As illustrated in FIG. 5, the first insulation layer IL1 may be disposed on the substrate portion SUB. The first insulation layer IL1 may be disposed on side surfaces of the adjacent substrate portions SUB in the first non-pixel region NPX, and may be in direct contact with the side surfaces of the adjacent substrate portions SUB. The first insulation layer IL1 may be in direct contact with an upper surface of the substrate portion SUB in each of the pixel regions PX_G1 and PX_R.

The second insulation layer IL2 may be disposed on the first insulation layer IL1. The second insulation layer IL2 may be disposed on a side surface of the substrate portion SUB in the first non-pixel region NPX, and may be in direct contact with the first insulation layer IL1 on the side surface of the substrate portion SUB. The second insulation layer IL2 may be disposed on a side surface of the first insulation layer IL1 and may be in direct contact with the side surface of the first insulation layer IL1. On a side surface of each of the substrate portions SUB adjacent to each other, the first insulation layers IL1 are disposed, and on a side surface of each of the first insulation layers IL1 disposed on the side surface of each of the adjacent substrate portions SUB, the second insulation layers IL2 are disposed. The first insulation layer IL1 may have a first width W1, the second insulation layer IL2 may have a second width W2, and the second width W2 may be greater than the first width W1, and a second width W2b in the second non-pixel region NPX may be greater than a second width W2a in the first non-pixel region NPX.

The first insulation layer IL1 and the second insulation layer IL2 may be disposed on each of the side surfaces of the adjacent substrate portions SUB. The second insulation layer IL2 may extend to the upper surface of the substrate portion SUB, and may be disposed on the first insulation layer IL1 on the upper surface of the substrate portion SUB. The second insulation layer IL2 may be in direct contact with the first insulation layer IL1 on the upper surface of the substrate portion SUB. The third insulation layer IL3 in FIG. 4 may not be disposed in the second non-pixel region NPX.

On the upper surface of the substrate portion SUB, the fourth insulation layer IL4 may be disposed on the second insulation layer IL2. The fourth insulation layer IL4 may be in direct contact with the second insulation layer IL2.

FIG. 6 is a graph showing a reflectance per wavelength of each different sample. FIG. 6 shows a reflectance according to the wavelength (nm) in a plurality of samples (S1, S2, S3). A width of the insulation layers of each of the samples (S1, S2, S3) may be different from each other. For example, each sample (S1, S2, S3) may have a lamination sequence of aluminum oxide (AlOx), hafnium oxide (HfOx), silicon oxide (SiOx), hafnium oxide (HfOx) and aluminum oxide (AlOx). Hereinafter, the lamination of each sample (S1, S2, S3) may be performed in the lamination sequence in a side surface direction of the non-pixel region NPX described in FIGS. 4 and 5.

In case of the first sample S1, thicknesses of aluminum oxide (AlOx), the hafnium oxide (HfOx), silicon oxide (SiOx), hafnium oxide (HfOx) and aluminum oxide (AlOx) may be 5/75/0/75/5 (nm), respectively.

In case of the second sample S2, thicknesses of aluminum oxide (AlOx), the hafnium oxide (HfOx), silicon oxide (SiOx), hafnium oxide (HfOx) and aluminum oxide (AlOx) may be 5/0/150/0/5 (nm), respectively.

In case of the third sample S3, thicknesses of aluminum oxide (AlOx), the hafnium oxide (HfOx), silicon oxide (SiOx), hafnium oxide (HfOx) and aluminum oxide (AlOx) may be 5/40/70/40/5 (nm), respectively.

In case of the first sample S1, a reflectance in the blue wavelength range may be high, and a reflectance in the green wavelength range may be the second highest, in case of the second sample S2, a reflectance in the green wavelength range may be the highest and a reflectance in the red wavelength range may be the second highest, and in case of the third sample S3, light reflectances according to the wavelengths are similar to those of the second sample S2, however, the reflectance in each of the green wavelength range and the red wavelength range may be lower than those of the second sample S2.

The lamination structure of the insulation layers of the first sample S1 may correspond to the lamination structure of the insulation layers IL1 and IL2 in the second non-pixel region NPX in FIG. 5, and the lamination structure of the insulation layers of the second sample S2 and the third sample S3 may correspond to the lamination structure of the insulation layers IL1, IL2 and IL3 in the first non-pixel region NPX in FIG. 4.

As seen in FIG. 6, by not disposing the third insulation layer (refer to IL3 in FIG. 4) in the second non-pixel region NPX of FIG. 5, the reflectance in the blue wavelength range and/or green wavelength range may be increased. Thus, it can be confirmed that the silicon oxide (SiOx) has a lower reflectance with respect to light in the blue wavelength range, and the hafnium oxide (HfOx) has a higher reflectance with respect to light in the blue wavelength range.

Further, it can be noted that in the first non-pixel region NPX in FIG. 4, the width W2 of the second insulation layer IL2 may be between the width W1 of the first insulation layer IL1 and the width W3 of the third insulation layer IL3, or when the second insulation layer IL2 is omitted, the reflectance with respect to light in the blue wavelength range and the red wavelength range is high.

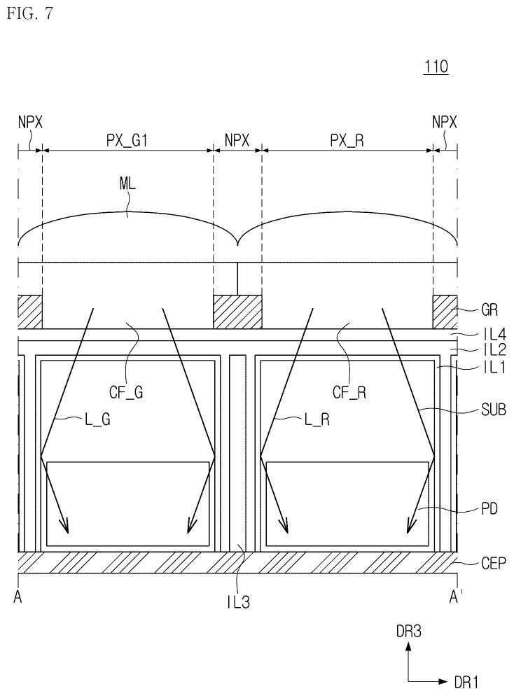

FIG. 7 is a schematic view illustrating light reflection of the pixel array according to an embodiment.

Referring to FIG. 7, as described above referring to FIGS. 4 and 6, the light L_G in the green wavelength range which passes through the first color filter CF_G is reflected based on the first to third insulation layers IL1 to IL3 disposed in the first non-pixel region NPX and enters back into the substrate portion SUB. The reflectance of the light L_G may be based on the lamination sequence and the design of the widths of the first to the third insulation layers IL1 to IL3 disposed in the first non-pixel region NPX. With this configuration, the reflectance with respect to the light L_G in the green wavelength range is improved in the first pixel region PX_G1, thereby improving the light receiving efficiency. In addition, the light L_R in the red wavelength range which passes through the second color filter CF_R is reflected based on the first to third insulation layers IL1 to IL3 disposed in the first non-pixel region NPX and enters back into the substrate portion SUB. The reflectance of the light L_G may be based on the lamination sequence and design of the widths of the first to the third insulation layers IL1 to IL3 disposed in the first non-pixel region NPX and the design of the width. With this configuration, the reflectance with respect to the light L_R in the red wavelength range is improved in the second pixel region PX_R, thereby improving the light receiving efficiency.

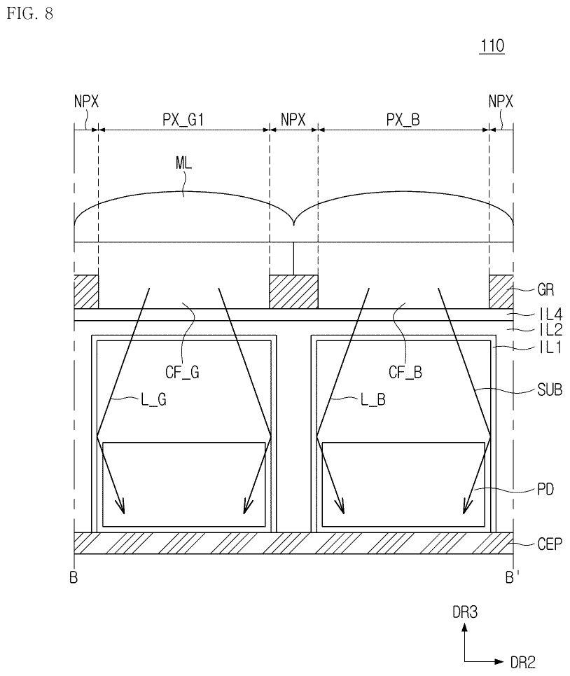

FIG. 8 is a schematic view illustrating light reflection of the pixel array according to an embodiment.

Referring to FIG. 8, as described above referring to FIGS. 5 and 6, the light L_B in the blue wavelength range which passes through the third color filter CF_B is reflected based on the first and second insulation layers IL1 and IL2 disposed in the first non-pixel region NPX and enters back into the substrate portion SUB. The reflectance of the light L_B may be based on through the lamination sequence and the design of the widths of the first and the second insulation layers IL1 to IL2 disposed in the first non-pixel region NPX. With this configuration, the reflectance with respect to the light L_B in the blue wavelength range is improved in the third pixel region PX_B, thereby improving the light receiving efficiency. Further, as seen in FIG. 6, the reflectance with respect to the light L_G in the green wavelength range can be improved through the lamination sequence of the first to the second insulation layers IL1 to IL2 and the design of the width.

Hereinafter, image sensing devices according to other embodiments will be described. With respect to the components which have been described referring to FIGS. 1 to 8, the redundant description thereof will be omitted.

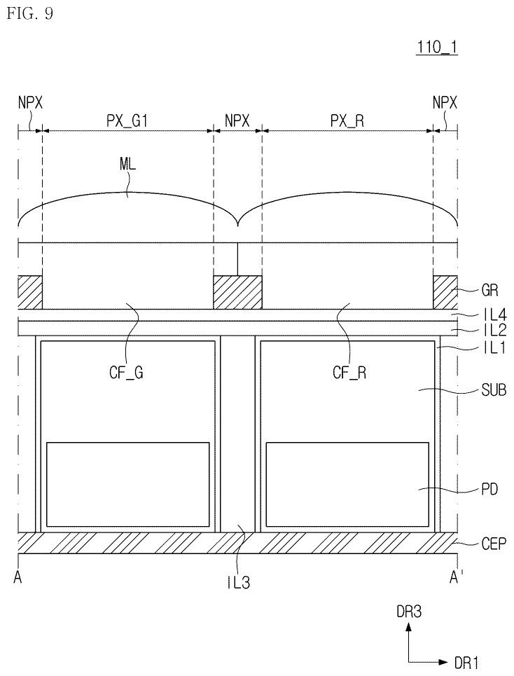

FIG. 9 is a cross-sectional view of a pixel array of an image sensing device according to another embodiment.

Referring to FIG. 9, a pixel array 110_1 of an image sensing device based on the implementation of the disclosed technology is different from the pixel array 110 according to FIG. 5 in that the second insulation layer IL2 in FIG. 4 is omitted.

In some implementations, the first insulation layers IL1 on a side surface of the substrate portions SUB in each pixel region PX_G1 and PX_R may be in direct contact with the third insulation layer IL3.

As described above referring to FIG. 6, it has been seen that in the first non-pixel region NPX, the width W2 of the second insulation layer IL2 may be between the width W1 of the first insulation layer IL1 and the width W3 of the third insulation layer IL3, or when the second insulation layer IL2 is omitted, the reflectance with respect to light in the blue wavelength range and the red wavelength range is high.

Therefore, according to the present disclosure, the reflectances with respect to the light L_R in the red wavelength range and the light L_G in the green wavelength range are improved in the first non-pixel region NPX, thereby improving the light receiving efficiency.

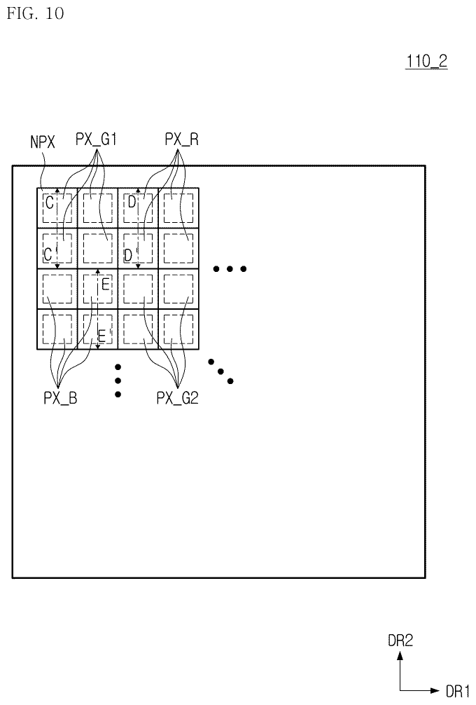

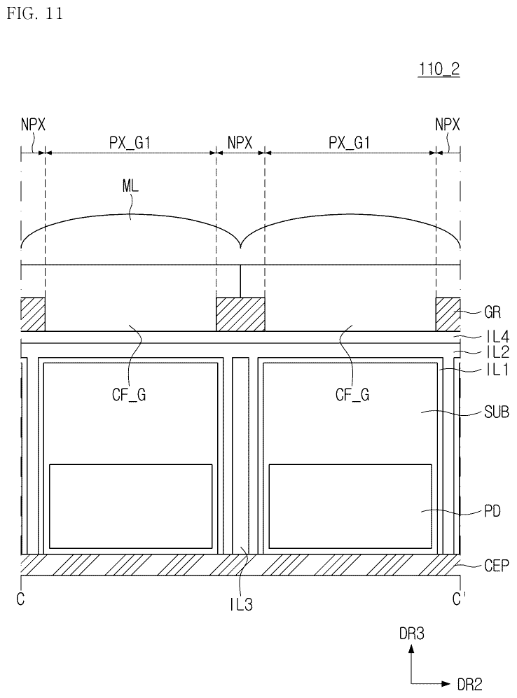

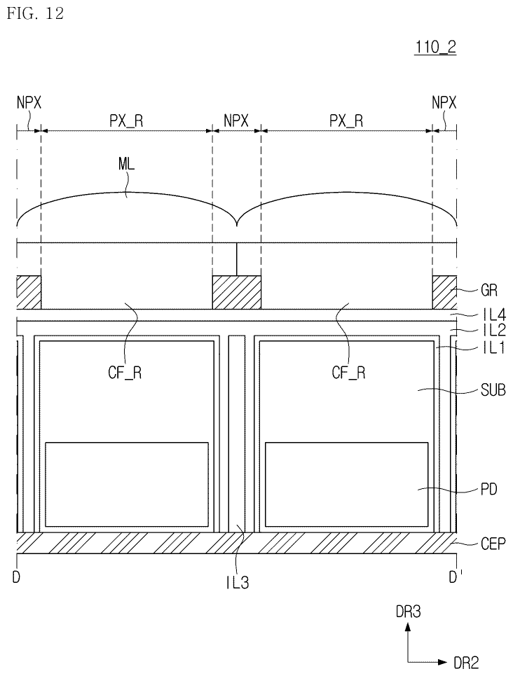

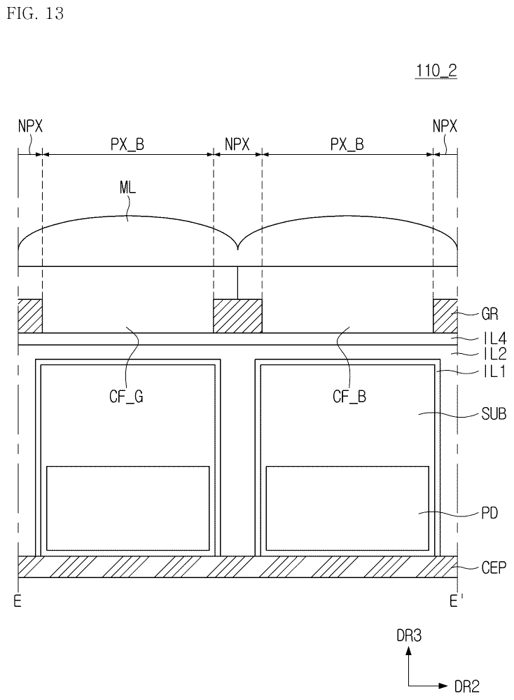

FIG. 10 is a plan view illustrating a pixel array of an image sensing device according to another embodiment in greater detail. FIG. 11 is a cross-sectional view taken along C-C′ line in FIG. 10. FIG. 12 is a cross-sectional view taken along D-D′ line in FIG. 10. FIG. 13 is a cross-sectional view taken along E-E′ line in FIG. 10.

Referring to FIG. 10, the pixel regions (PX_G1, PX_R, PX_B, PX_G2) of a pixel array 110_2 of an image sensing device according to the present disclosure are different from the pixel array 110 according to FIG. 3 in that each of the pixel regions (PX_G1, PX_R, PX_B, PX_G2) includes a plurality of sub-pixel regions (PX_G1, PX_R, PX_B, PX_G2), respectively. Each of the plurality of sub-pixel regions (PX_G1, PX_R, PX_B, PX_G2) disposed in a two-by-two arrangement is given as an example, but the embodiments of the present disclosure are not limited thereto, and may be disposed in a three-by-three or higher arrangement. The non-pixel regions NPX may be disposed between the plurality of sub-pixel regions configuring one pixel region (PX_G1, PX_R, PX_B, PX_G2).

Referring to FIG. 11, the lamination structure and the design of the width of the insulation layers IL1, IL2 and IL3 disposed in the non-pixel region NPX in a boundary between the plurality of sub-pixels PX_G1 in the first pixel region PX_G1 may be the same with the lamination structure and the design of the width of the insulation layers IL1, IL2 and IL3 disposed in the non-pixel region NPX in a boundary between the first pixel region PX_G1 and the second sub-pixel PX_R in FIG. 4.

In some embodiments, the lamination structure and the design (or structure) of the width of the insulation layers disposed in the non-pixel region NPX in a boundary between the plurality of sub-pixels PX_G1 in the first pixel region PX_G1 may be the same with the lamination structure and the design of the width of the insulation layers IL1 and IL3 disposed in the non-pixel region NPX in a boundary between the first pixel region PX_G1 and the second sub-pixel PX_R in FIG. 9.

Referring to FIG. 12, the lamination structure and the design (or structure) of the width of the insulation layers IL1, IL2 and IL3 disposed in the non-pixel region NPX in a boundary between the plurality of sub-pixels PX_G1 in the second pixel region PX_R may be the same with the lamination structure and the design of the width of the insulation layers IL1, IL2 and IL3 disposed in the non-pixel region NPX in a boundary between the first pixel region PX_G1 and the second sub-pixel PX_R in FIG. 4.

In some embodiments, the lamination structure and the design (or structure) of the width of the insulation layers disposed in the non-pixel region NPX in a boundary between the plurality of sub-pixels PX_G1 in the second pixel region PX_R may be the same with the lamination structure and the design of the width of the insulation layers IL1 and IL3 disposed in the non-pixel region NPX in a boundary between the first pixel region PX_G1 and the second sub-pixel PX_R in FIG. 9.

Referring to FIG. 13, the lamination structure and the design (or structure) of the width of the insulation layers IL1 and IL2 disposed in the non-pixel region NPX in a boundary between the plurality of sub-pixels PX_G1 in the third pixel region PX_B may be the same with the lamination structure and the design of the width of the insulation layers IL1 and IL2 disposed in the non-pixel region NPX in a boundary between the first pixel region PX_G1 and the third sub-pixel PX_B in FIG. 5.

The description of other components, which have been provided referring to FIGS. 1 and 6, will be omitted.

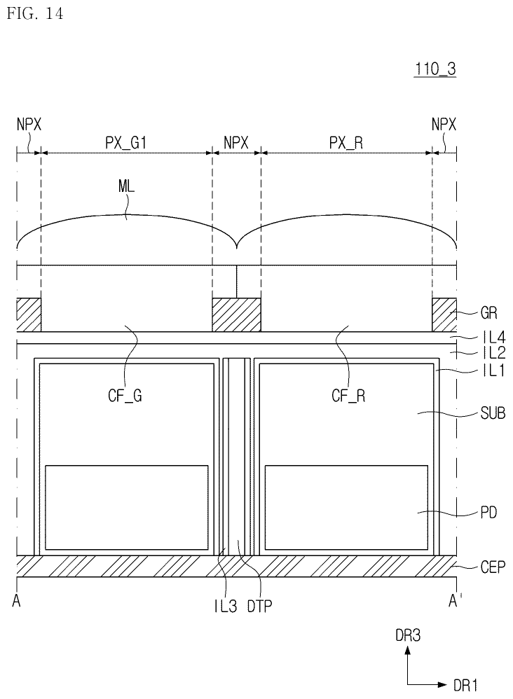

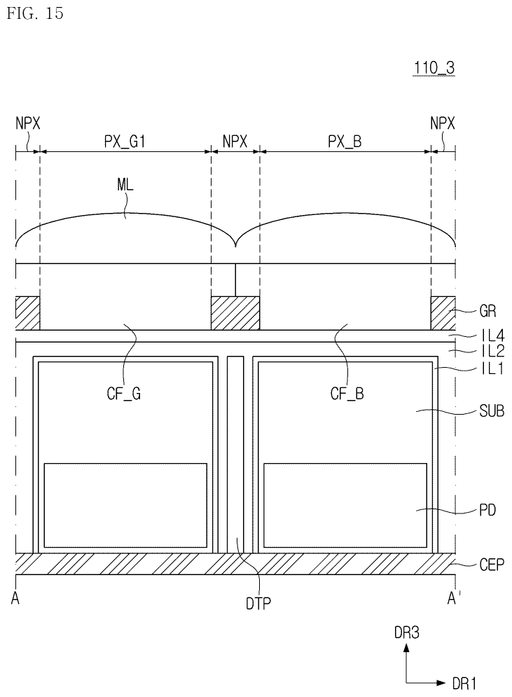

FIG. 14 is a cross-sectional view illustrating a pixel array of an image sensing device according to another embodiment. FIG. 15 is a cross-sectional view illustrating a pixel array of an image sensing device according to still another embodiment.

Referring to FIGS. 14 and 15, a pixel array 110_3 of an image sensing device according to the present disclosure is different from the pixel array 110 according to FIG. 4 in that the pixel array 110_3 further includes a separating portion DTP disposed in the non-pixel region NPX. The acronym DPT for the deep trench portion is used for the separating portion but the separating portion may be implemented in various manners without being limited to the deep trench portion.

In some implementations, an electric field may be applied to the separating portion DTP. In some implementations, the separating portion DTP may include a suitable electrically conducting material to which an electric field can be applied. One example of a material for the separating portion DTP is an electrically conductive poly-silicon material.

Referring to FIG. 14, in the first non-pixel region NPX, the third insulation layer IL3 is disposed between a side surface of the substrate portion SUB and the separating portion DTP, and the third insulation layer IL3 may be in direct contact with the separating portion DTP. The second insulation layer IL2 is disposed between the side surface of the substrate portion SUB and the third insulation layer IL3 and the second insulation layer IL2 may be in direct contact with the third insulation layer IL3. The first insulation layer IL1 is disposed between the side surface of the substrate portion SUB and the second insulation layer IL2 and the first insulation layer IL1 may be in direct contact with the side surface of the substrate portion SUB and the second insulation layer IL2.

Each of the first insulation layers IL1 is disposed on each of the side surfaces of the substrate portions SUB of adjacent pixel regions PX_G1 and PX_R, each of the second insulation layers IL2 is disposed between each of the first insulation layers IL1, each of the third insulation layers IL3 is disposed between each of the second insulation layers IL2, and the separating portion DTP may be disposed between each of the third insulation layers IL3.

Referring to FIG. 15, in the second non-pixel region NPX, the second insulation layer IL2 is disposed between the side surface of the substrate portions SUB and the separating portion DTP, and the second insulation layer IL2 may be in direct contact with the separating portion DTP. The first insulation layer IL1 is disposed between the side surface of the substrate portions SUB and the second insulation layer IL2, and the first insulation layer IL1 may be in direct contact with the second insulation layer IL2.

Each of the first insulation layers IL1 may be disposed on each of the side surfaces of the substrate portions SUB, and each of the second insulation layers IL2 may be disposed between each of the first insulation layers IL1, and the separating portion DTP may be disposed between each of the second insulation layers IL2.

As described above referring to FIGS. 4 to 6, the light L_G in the green wavelength range which passes through the first color filter CF_G is reflected through the lamination sequence of the first to the third insulation layers IL1 to IL3 disposed in the first non-pixel region NPX and the design of the width, and becomes incident into the substrate portion SUB. With this configuration, the reflectance with respect to the light L_G in the green wavelength range is improved in the first pixel region PX_G1, thereby improving the light receiving efficiency. In addition, the light L_R in the red wavelength range which passes through the second color filter CF_R is reflected through the lamination sequence of the first to the third insulation layers IL1 to IL3 disposed in the first non-pixel region NPX and the design of the width, and becomes incident into the substrate portion SUB. With this configuration, the reflectance with respect to the light L_R in the red wavelength range is improved in the second pixel region PX_R, thereby improving the light receiving efficiency.

In addition, the light L_B in the blue wavelength range which passes through the third color filter CF_B is reflected through the lamination sequence of the first to the second insulation layers IL1 to IL2 disposed in the first non-pixel region NPX and the design of the width, and becomes incident into the substrate portion SUB. With this configuration, the reflectance with respect to the light L_B in the blue wavelength range is improved in the third pixel region PX_B, thereby improving the light receiving efficiency. Further, as seen in FIG. 6, the reflectance with respect to the light L_G in the green wavelength range can be improved through the lamination sequence of the first to the second insulation layers IL1 to IL2 and the design of the width.

The description of other components, which have been provided referring to FIGS. 1 and 6, will be omitted.

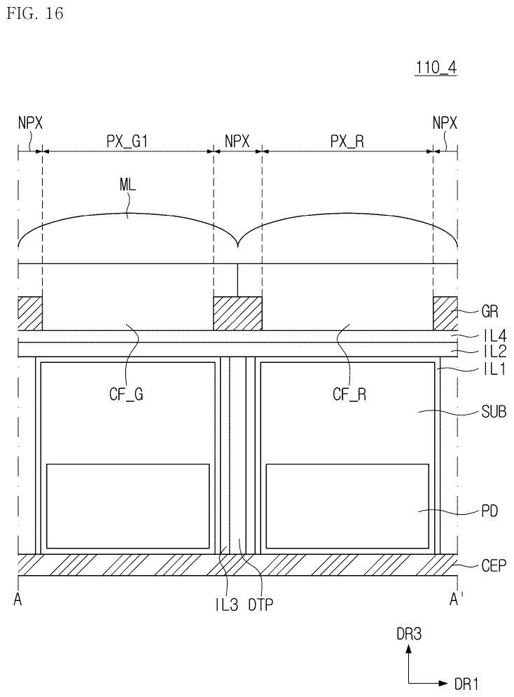

FIG. 16 is a cross-sectional view illustrating a pixel array of an image sensing device according to still another embodiment.

Referring to FIG. 16, a pixel array 110_4 of an image sensing device according to the present embodiment is different from the pixel array 110_3 in FIG. 14 in that the second insulation layer IL2 is omitted in the pixel array 110_4.

In some implementations, the first insulation layers IL1 on the side surface of the substrate portion SUB in each pixel region PX_G1 and PX_R may be in direct contact with the third insulation layer IL3.

As described above referring to FIG. 6, it is seen that in the first non-pixel region NPX, the width W2 of the second insulation layer IL2 may be between the width W1 of the first insulation layer IL1 and the width W3 of the third insulation layer IL3, or when the second insulation layer IL2 is omitted, the reflectance with respect to light in the blue wavelength range and the red wavelength range is high.

Therefore, various implementations of the disclosed technology provide an image sensing device which can improve the reflectances with respect to the light in the red wavelength range and the light in the green wavelength range in the first non-pixel region NPX, thereby improving the light receiving efficiency.

The image sensing device according to various embodiments of the present disclosure may be described as below.

One embodiment is an image sensing device, including: a circuit portion including a first pixel region, a second pixel region positioned in a first direction of the first pixel region, a third pixel region positioned in a second direction of the first pixel region, a first non-pixel region between the first pixel region and the second pixel region, and a second non-pixel region between the first pixel region and the third pixel region; a substrate portion disposed on the circuit portion, including a photoelectric conversion element disposed in the first pixel region to the third pixel region, respectively, and including a hole formed in the non-pixel region; and at least one insulation layer on the substrate portion, and kinds of the at least one insulation layer disposed in the first non-pixel region and the at least one insulation layer disposed in the second non-pixel region may be different from each other.

In the image sensing device according to various embodiments, the first pixel region receives a first light, the second pixel region receives a second light, the third pixel region receives a third light, a reflectance of the at least one insulation layer disposed in the first non-pixel region with respect to the first light or the second light is greater than a reflectance thereof with respect to the third light, and a reflectance of the at least one insulation layer disposed in the second non-pixel region with respect to the first light or the third light is greater than a reflectance thereof with respect to the first light.

In the image sensing device according to various embodiments, in the first non-pixel region, the at least one insulation layer may include first insulation layers on a side surface of the substrate portion in the first pixel region and on a side surface of the substrate portion in the second pixel region, second insulation layers on a side surface of each of the first insulation layers, and a third insulation layer between the second insulation layers adjacent to each other, and in the first non-pixel region, the first insulation layer may be in direct contact with the second insulation layer, and the second insulation layer may be in direct contact with the third insulation layer.

In the image sensing device according to various embodiments, a width of the second insulation layer may be greater than a width of the first insulation layer and smaller than a width of the third insulation layer.

In the image sensing device according to various embodiments, the first insulation layer may extend to an upper surface of the substrate portion in the first pixel region and an upper surface of the substrate portion in the second pixel region, and the second insulation layer may be disposed on the first insulation layer extended to the upper surface of the substrate portion in the first pixel region and the first insulation layer extended to the upper surface of the substrate portion in the second pixel region, respectively.

In the image sensing device according to various embodiments, the first insulation layer may include aluminum oxide (AlOx), the second insulation layer may include hafnium oxide (HfOx) or tantalum oxide (TaOx), and the third insulation layer may include silicon oxide (SiOx).

In the image sensing device according to various embodiments, in the first non-pixel region, the at least one insulation layer may include first insulation layers on a side surface of the substrate portion in the first pixel region and on a side surface of the substrate portion in the second pixel region, and a third insulation layer between the first insulation layers adjacent to each other, and in the first non-pixel region, the first insulation layer may be in direct contact with the third insulation layer.

In the image sensing device according to various embodiments, in the second non-pixel region, the at least one insulation layer may include first insulation layers on a side surface of the substrate portion in the first pixel region and on a side surface of the substrate portion in the second pixel region, and second insulation layers on a side surface of each of the first insulation layers.

In the image sensing device according to various embodiments, a width of the second insulation layer may be greater than a width of the first insulation layer.

In the image sensing device according to various embodiments, in the second non-pixel region, the first insulation layer may be in direct contact with the second insulation layer.

In the image sensing device according to various embodiments, the first insulation layer may extend to an upper surface of the substrate portion in the first pixel region and an upper surface of the substrate portion in the third pixel region, and the second insulation layer may be disposed on the first insulation layer extended to the upper surface of the substrate portion in the first pixel region and the first insulation layer extended to the upper surface of the substrate portion in the third pixel region, respectively.

In the image sensing device according to various embodiments, the hole may completely pass through the substrate portion.

In the image sensing device according to various embodiments, each of the first to the third pixel regions may include a plurality of sub-pixel regions, and the at least one insulation layer disposed in the non-pixel region between the plurality of sub-pixel regions of the first pixel region may be the same as the at least one insulation layer disposed in the first non-pixel region.

In the image sensing device according to various embodiments, the at least one insulation layer disposed in the non-pixel region between the plurality of sub-pixel regions of the second pixel region may be the same as the at least one insulation layer disposed in the first non-pixel region.

In the image sensing device according to various embodiments, the at least one insulation layer disposed in the non-pixel region between the plurality of sub-pixel regions of the third pixel region may be the same as the at least one insulation layer disposed in the second non-pixel region.

Another embodiment is an image sensing device, including: a circuit portion including a first pixel region, a second pixel region positioned in a first direction of the first pixel region, a third pixel region positioned in a second direction of the first pixel region, a first non-pixel region between the first pixel region and the second pixel region, and a second non-pixel region between the first pixel region and the third pixel region; a substrate portion disposed on the circuit portion, including a photoelectric conversion element disposed in the first pixel region to the third pixel region, respectively, and including a hole formed in the non-pixel region; a separating portion disposed in the first non-pixel region and the second non-pixel region, respectively; and at least one insulation layer between the separating portion and a side surface of the substrate portion, and the at least one insulation layer disposed in the first non-pixel region and the at least one insulation layer disposed in the second non-pixel region may be different from each other.

In the image sensing device according to various embodiments, the first pixel region may receive a first light, the second pixel region may receive a second light, the third pixel region may receive a third light, a reflectance of the at least one insulation layer disposed in the first non-pixel region with respect to the first light or the second light may be greater than a reflectance thereof with respect to the third light, and a reflectance of the at least one insulation layer disposed in the second non-pixel region with respect to the first light or the third light may be greater than a reflectance thereof with respect to the first light.

In the image sensing device according to various embodiments, in the first non-pixel region, the at least one insulation layer may include first insulation layers between the substrate portion in the first pixel region and the separating portion and between the substrate portion in the second pixel region and the separating portion, and third insulation layers between each of the second insulation layers and the separating portion, and the first insulation layer may include aluminum oxide (AlOx), the second insulation layer may include hafnium oxide (HfOx) or tantalum oxide (TaOx), the third insulation layer may include silicon oxide (SiOx), and the separating portion may include poly-silicon.

In the image sensing device according to various embodiments, in the first non-pixel region, the at least one insulation layer may include first insulation layers between the substrate portion in the first pixel region and the separating portion and between the substrate portion in the second pixel region and the separating portion, and third insulation layers between each of the first insulation layers and the separating portion, and the first insulation layer and the third insulation layer may be in direct contact with each other.

In the image sensing device according to various embodiments, in the second non-pixel region, the at least one insulation layer may include first insulation layers on a side surface of the substrate portion in the first pixel region and on a side surface of the substrate portion in the second pixel region, and second insulation layers on a side surface of each of the first insulation layers, and the second insulation layer may be in direct contact with the separating portion.

While various embodiments have been described with reference to the exemplified drawings, variations and improvements of the disclosed embodiments and other embodiments may be made based on what is described or illustrated in this document.

I/We claim:

1. An image sensing device, comprising:
a substrate;
a first pixel region supported by the substrate;
a second pixel region positioned in a first direction of the first pixel region and supported by the substrate;
a third pixel region positioned in a second direction of the first pixel region and supported by the substrate, wherein each of the first pixel region, the second pixel region, and the third pixel region includes one or more photoelectric conversion elements configured to produce electrical signals in response to incident light,
a first non-pixel region that does not include a photoelectric conversion element for detecting incident light and is located between the first pixel region and the second pixel region to reflect light from the first pixel region back to the first pixel region and reflect light from the second pixel region back to the second pixel region;
a second non-pixel region that does not include a photoelectric conversion element for detecting incident light and is located between the first pixel region and the third pixel region to reflect light from the first pixel region back to the first pixel region and reflect light from the third pixel region back to the third pixel region;
at least one first insulation material and at least one second insulation material that are disposed in the first non-pixel region and the second non-pixel region, respectively; and
wherein the at least one first insulation material disposed in the first non-pixel region is different from the at least one second insulation material disposed in the second non-pixel region.

2. The image sensing device of claim 1,
wherein the first pixel region, the second pixel region, and the third pixel region are configured to transmit light in a first color, light in a second color, light in a third color, respectively, and wherein a reflectance of the at least one first insulation material with respect to the light in the first color or the light in the second color is greater than a reflectance of the at least one first insulation material with respect to the light in the third color, and a reflectance of the at least one second insulation material disposed in the second non-pixel region with respect to the light in the first color or the light in the third color is greater than a reflectance of the at least one second insulation material with respect to the light in the first color.

3. The image sensing device of claim 1,
wherein the at least one first insulation material includes a first insulation layer on side surfaces of the substrate in the first pixel region and the second pixel region, a second insulation layer on a side surface of the first insulation layer, and a third insulation layer between two adjacent portions of the second insulation layer, and
wherein in the first non-pixel region, the first insulation layer is in direct contact with the second insulation layer, and the second insulation layer is in direct contact with the third insulation layer.

4. The image sensing device of claim 3,
wherein a width of the second insulation layer is greater than a width of the first insulation layer and smaller than a width of the third insulation layer.

5. The image sensing device of claim 3,
wherein the first insulation layer extends to an upper surface of the substrate in the first pixel region and an upper surface of the substrate in the second pixel region, and wherein the second insulation layer is disposed on the first insulation layer extended to the upper surface of the substrate in the first pixel region and the first insulation layer extended to the upper surface of the substrate in the second pixel region.

6. The image sensing device of claim 3,
wherein the first insulation layer includes aluminum oxide (AlOx), the second insulation layer includes hafnium oxide (HfOx) or tantalum oxide (TaOx), and the third insulation layer includes silicon oxide (SiOx).

7. The image sensing device of claim 1,
wherein the at least one first insulation material includes a first insulation layer on side surfaces of the substrate in the first pixel region and the second pixel region, and a third insulation layer between two adjacent portions of the first insulation layer, and wherein in the first non-pixel region, the first insulation layer is in direct contact with the third insulation layer.

8. The image sensing device of claim 1,
wherein the at least one second insulation material includes a first insulation layer on side surfaces of the substrate in the first pixel region and the second pixel region, and a second insulation layer on a side surface of the first insulation layer.

9. The image sensing device of claim 8,
wherein a width of the second insulation layer is greater than a width of the first insulation layer.

10. The image sensing device of claim 8,
wherein in the second non-pixel region, the first insulation layer is in direct contact with the second insulation layer.

11. The image sensing device of claim 8,
wherein the first insulation layer extends to an upper surface of the substrate in the first pixel region and an upper surface of the substrate in the third pixel region, and wherein the second insulation layer is disposed on the first insulation layer extended to the upper surface of the substrate in the first pixel region and the first insulation layer extended to the upper surface of the substrate in the third pixel region.

12. The image sensing device of claim 1,
wherein the substrate includes a hole completely passing through the substrate.

13. The image sensing device of claim 1,
wherein each of the first pixel region, the second pixel region, and the third pixel region includes a plurality of sub-pixel regions, and the at least one first insulation material is further disposed in a non-pixel region between the plurality of sub-pixel regions of the first pixel region.

14. The image sensing device of claim 13,
wherein the at least one first insulation material is further disposed in a non-pixel region between the plurality of sub-pixel regions of the second pixel region.

15. The image sensing device of claim 13,
wherein the at least one first insulation material is further disposed in a non-pixel region between the plurality of sub-pixel regions of the third pixel region.

16. An image sensing device, comprising:
a substrate including a first pixel region that includes one or more photoelectric conversion elements detecting incident light, a second pixel region that is positioned in a first direction of the first pixel region and includes one or more photoelectric conversion elements detecting incident light, a third pixel region that is positioned in a second direction of the first pixel region and includes one or more photoelectric conversion elements detecting incident light, a first non-pixel region that is located between the first pixel region and the second pixel region and does not detect incident light, and a second non-pixel region that is located between the first pixel region and the third pixel region and does not detect incident light, the substrate further including a hole in at least one of the first non-pixel region or the second non-pixel region;
a separating structure disposed in the first non-pixel region and the second non-pixel region; and
at least one first insulation material disposed in the first non-pixel region and between the separating structure and a side surface of the substrate,
at least one second insulation material disposed in the second non-pixel region and between the separating structure and a side surface of the substrate,
wherein the at least one first insulation material disposed in the first non-pixel region and the at least one second insulation material disposed in the second non-pixel region are different from each other.

17. The image sensing device of claim 16,
wherein the first pixel region, the second pixel region, and the third pixel region are configured to transmit light in a first color, light in a second color, light in a third color, respectively, and wherein a reflectance of the at least one first insulation material with respect to the light in the first color or the light in the second color is greater than a reflectance of the at least one first insulation material with respect to the light in the third color, and a reflectance of the at least one second insulation material with respect to the light in the first color or the light in the third color is greater than a reflectance of the at least one second insulation material with respect to the light in the first color.

18. The image sensing device of claim 16,
wherein the at least one first insulation material includes a first insulation layer between the substrate in the first pixel region and the separating structure and between the substrate in the second pixel region and the separating structure, a second insulation layer between the first insulation layer and the separating structure, and a third insulation layer between the second insulation layer and the separating structure, and wherein the first insulation layer includes aluminum oxide (AlOx), the second insulation layer includes hafnium oxide (HfOx) or tantalum oxide (TaOx), the third insulation layer includes silicon oxide (SiOx), and the separating structure includes poly-silicon.

19. The image sensing device of claim 16,
wherein the at least one first insulation material includes a first insulation layer between the substrate in the first pixel region and the separating structure and between the substrate in the second pixel region and the separating structure, and a third insulation layer between the first insulation layer and the separating structure, and wherein the first insulation layer and the third insulation layer are in direct contact with each other.

20. The image sensing device of claim 16,
wherein the at least one second insulation material includes a first insulation layer on side surfaces of the substrate in the first pixel region and the second pixel region, and a second insulation layer on a side surface of the first insulation layer, and wherein the second insulation layer is in direct contact with the separating structure.
